(19) United States
(12) Patent Application Publication
(10) Pub. No.: US 2021/0341830 A1
(43) Pub. Date: Nov. 4, 2021

(54) PATTERN FORMING METHOD, PHOTOMASK SUBSTRATE CREATION METHOD, PHOTOMASK CREATION METHOD, AND PHOTOMASK

(71) Applicant: Kioxia Corporation, Tokyo (JP)

(72) Inventors: Yukio OPPATA, Chiba Chiba (JP); Shoji MIMOTOGI, Yokohama Kanagawa (JP)

(73) Assignee: Kioxia Corporation, Tokyo (JP)

(21) Appl. No.: 17/197,978

(22) Filed: Mar. 10, 2021

(30) Foreign Application Priority Data
Mar. 23, 2020 (JP) 2020-050569

(51) Int. Cl. G03F 1/38; G03F 1/62

(52) U.S. Cl. CPC G03F 1/38; G03F 1/62

(57) ABSTRACT

A pattern forming method of an embodiment includes: obtaining a height difference of a transfer surface of a substrate to which a pattern is to be transferred; measuring a focus shift tracking amount with respect to the height difference of an exposure apparatus that performs pattern transfer; calculating a difference between the height difference and the tracking amount; forming a photomask provided with an optical path difference corresponding to the difference; and transferring a pattern to the substrate using the photomask.

### CROSS-REFERENCE TO RELATED APPLICATIONS

This application is based upon and claims the benefit of priority from Japanese Application No. 2020-050569, filed on Mar. 23, 2020, the entire contents of which are incorporated herein by reference.

### FIELD

Embodiments described herein relate generally to a pattern forming method, a photomask substrate creation method, a photomask creation method, and a photomask.

### BACKGROUND

In recent years, due to the three-dimensionalization (3D) of memory, a step between a cell region and a peripheral circuit region of a semiconductor wafer has become remarkable. This step cannot be sufficiently tracked by a focal position correction function of an exposure apparatus performed when a transfer pattern is exposed on a wafer using a photomask from the viewpoint of correction accuracy, and yield loss is caused due to transfer failure.

### BRIEF DESCRIPTION OF THE DRAWINGS

FIG. 1 is an explanatory diagram of an example of an exposure apparatus of an embodiment;

FIG. 2 is an explanatory diagram of a principle of the embodiment;

FIG. 3 is a processing flowchart of pattern transfer of the embodiment;

FIG. 4 is an explanatory diagram of an example of a surface shape (cross-sectional shape) of a resist;

FIG. 5 is an explanatory diagram of a configuration example of a photomask of a first embodiment corresponding to the resist of FIG. 4;

FIG. 6 is an explanatory diagram of a configuration example of a photomask of a second embodiment corresponding to the resist of FIG. 4;

FIG. 7 is an explanatory diagram of a configuration example of a photomask of a third embodiment corresponding to the resist of FIG. 4;

FIG. 8 is an explanatory diagram of a configuration example of a photomask of a fourth embodiment corresponding to the resist of FIG. 4;

FIGS. 9A and 9B are explanatory diagrams of a fifth embodiment;

FIGS. 10A to 10G are flowcharts of first creation processing of a photomask substrate of the first embodiment;

FIGS. 11A to 11G are flowcharts of second creation processing of the photomask substrate of the first embodiment;

FIGS. 12A to 12D are flowcharts of light-shielding body forming processing;

FIGS. 13A to 13G are flowcharts of creation processing of a photomask substrate of the second embodiment;

FIGS. 14A to 14D are flowcharts of creation processing of a photomask substrate of a sixth embodiment; and

FIGS. 15A to 15F are explanatory diagrams of another creation method of an optical path difference adjusting member used in the sixth embodiment.

### DETAILED DESCRIPTION

A pattern forming method comprising: preparing a photomask including at least a photomask substrate and a plurality of light-shielding bodies formed on the photomask substrate, the photomask including a first region having a first height, a second region having a second height different from the first height, and a slope provided between the first region and the second region and connecting the first height and the second height; and transferring a pattern to a substrate using the photomask.

Next, a preferred embodiment will be described with reference to the drawings.

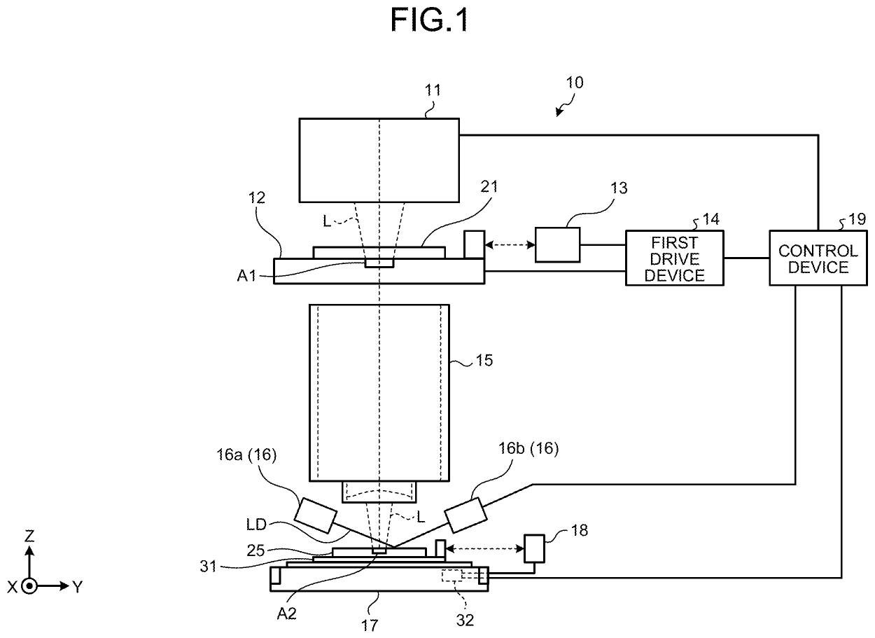

FIG. 1 is an explanatory diagram of an example of an exposure apparatus of an embodiment.

In FIG. 1, the direction toward the front side on the vertical line of the paper of the drawing is referred to as an X-axis direction, the direction toward the right side of the paper of the drawing is referred to as a Y-axis direction, and the direction toward the upper side of the paper of the drawing is referred to as a Z-axis direction. The direction toward the upper side of the paper of the drawing corresponds to the upward direction in the height direction of an exposure apparatus 10. The X-axis, Y-axis, and Z-axis are orthogonal to each other.

In the following description, as the exposure apparatus 10, an apparatus adopting the step-and-scan method is taken as an example, but the embodiment can also be applied to an exposure apparatus adopting another method.

The exposure apparatus 10 includes a lighting unit 11, a photomask (reticle) stage 12, a first interferometer 13, a first drive device 14, a projection unit 15, a focus sensor 16, a wafer stage 17, a second interferometer 18, and a control device 19.

In the above configuration, the photomask stage 12 supports a photomask 21 on which a circuit pattern is formed.

The first drive device 14 includes, for example, a plurality of drive motors. The first drive device 14 can move the photomask stage 12 at least on an XY plane. By moving the photomask stage 12, the photomask 21 is moved.

In this case, a position of the photomask stage 12 is measured by the first interferometer 13. A measurement result of the first interferometer 13 is fed back to the first drive device 14. As a result, the first drive device 14 performs position control of the photomask stage 12 based on the measurement result by the first interferometer 13.

The wafer stage 17 movably supports a wafer 25. Specifically, the wafer stage 17 includes a wafer chuck 31 on which the wafer 25 is placed and a second drive device 32 that moves the wafer chuck 31.

The second drive device 32 includes, for example, a plurality of motors. The second drive device 32 can move the wafer chuck 31 in the X-axis direction, the Y-axis direction, and the Z-axis direction. The second drive device 32 can control an inclination of the wafer chuck 31. The inclination is, for example, an inclination (Ry) in the X direction with the Y axis as the rotation axis and an inclination (Rx) in the Y direction with the X axis as the rotation axis.

Here, a position of the wafer chuck 31 is measured by the second interferometer 18. A measurement result of the second interferometer 18 is fed back to the second drive device 32. As a result, the second drive device 32 performs position control of the wafer chuck 31 using the measurement result by the second interferometer 18. By moving the wafer chuck 31 by the second drive device 32, the wafer 25 placed on the wafer chuck 31 is moved.

The lighting unit 11 irradiates a range of a region A1 on the photomask 21 with exposure light L. The projection unit 15 projects the exposure light L transmitted through the photomask 21 onto a range of a region A2 on a surface of the wafer 25. As a result, the circuit pattern drawn on the photomask 21 is transferred to the wafer 25. The projection unit 15 is also called a projection optical system (reduced projection optical system). The region A1 is called an exposure slit.

A resist (film) is formed on the surface of the wafer 25 at the time of exposure. Therefore, the exposure light L is, to be exact, emitted to the resist (film). A projected image of the circuit pattern is imaged on the surface of the resist. Hereinafter, the surface of the wafer 25 refers to the surface of the resist formed on the wafer 25 unless otherwise specified.

The focus sensor 16 is a measuring device that measures topography on the surface of the wafer 25. The focus sensor 16 includes a projection unit 16a and a detection unit 16b.

The projection unit 16a emits light flux of detection light LD toward the wafer 25. Here, each of the wavelength of the light flux of the detection light LD and the irradiation angle of the light flux is set so that the light flux is reflected on the surface of the wafer 25.

The detection unit 16b receives and detects the light flux of the reflected detection light LD.

The detection unit 16b acquires the topography of the surface of the wafer 25 based on the result of detecting the light flux of the detection light LD.

A diffraction grating (not shown) is provided in each of the inside of the projection unit 16a and the inside of the detection unit 16b, respectively.

The diffraction grating is provided with a plurality of slits (openings) arranged at equal intervals.

The light flux emitted from the different slits of the diffraction grating of the projection unit 16a is emitted to different positions on the surface of the wafer 25 and reflected.

The detection unit 16b receives the light flux reflected at each position through different slits, and acquires topography measurement data individually for each slit.

Therefore, the focus sensor 16 can acquire measurement data of the topography of the surface of the wafer 25 from a plurality of measurement points corresponding to the plurality of slits in one processing.

In the subsequent embodiments, it is assumed that the pattern formed on the photomask 21 is formed on the resist on the wafer 25 by using the exposure apparatus as described above.

Here, the principle of the embodiment will be described.

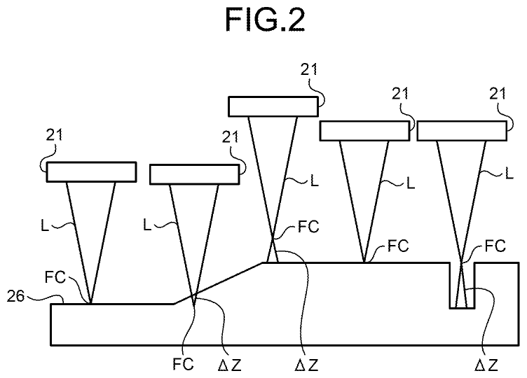

FIG. 2 is an explanatory diagram of a principle of the embodiment.

As illustrated in FIG. 2, the surface of the resist 26, which is the surface to be transferred of the pattern on the wafer 25 as a semiconductor substrate (board), is not flat due to the unevenness of the substructure thereof, and may have steps.

By the way, the exposure apparatus 10 has a focus shift function of measuring a step on the surface of the resist 26 at the time of transfer and adjusting a focal position FC in the Z direction (thickness direction of the wafer 10). However, it is not possible to follow all the steps, and the amount that can be followed changes depending on the width of the step region and the location of the step on the wafer 25, and a tracking residual ΔZ for steps that cannot be followed remains. Hereinafter, adjusting the focal position FC in the Z direction is referred to as focus shift, in some cases. Here, “tracking” refers to matching the leveling (focus position) of the exposure apparatus with a plane (least squares plane) at which the sum of squares of the distances from any points of the exposed portion is minimized on a substrate having a step.

Here, the “following residual ΔZ” refers to an amount of deviation at each point from the above-mentioned least squares plane. The “following amount” described later refers to an amount that can be followed by changing the focus.

If the tracking residual ΔZ that cannot be tracked by the focus shift function of the exposure apparatus 10 described above is within the range of the depth of focus calculated from the transfer pattern and the lighting conditions, it is possible to transfer a pattern on the surface of the resist 26 on the wafer 25 with desired accuracy.

However, if the tracking residual ΔZ that cannot be tracked by the focus shift function of the exposure apparatus 10 exceeds the range of the depth of focus, the pattern cannot be transferred with desired accuracy, causing transfer failure and yield loss.

Particularly in recent years, the depth of focus has been decreasing due to the miniaturization of transfer patterns and the complication of lighting conditions. Further, in a semiconductor memory, as a circuit structure becomes three-dimensional, the difference that cannot be tracked increases, and it is difficult to transfer a pattern on a surface of a resist with a desired accuracy.

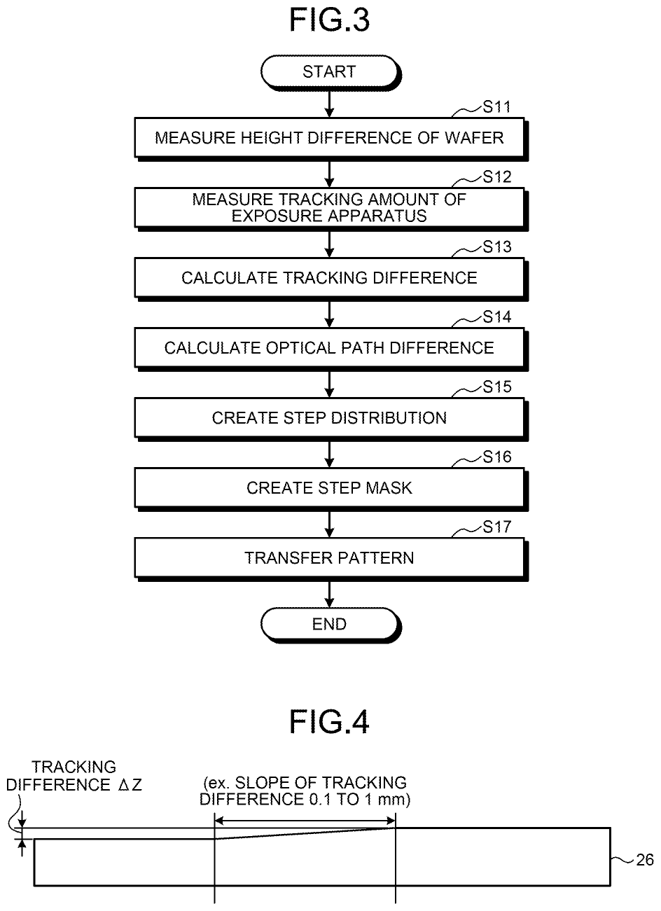

FIG. 3 is a processing flowchart of pattern transfer of the embodiment.

First, in the present embodiment, the shape of the surface of the resist 26 (the height difference of the unevenness of the surface of the resist 26) of the wafer 25 to which the pattern is transferred is measured in advance (Step S11).

Next, the focus shift control is performed in order to achieve the focus function using the exposure apparatus 10 that performs exposure, and the tracking amount of the exposure apparatus 10 is measured (Step S12).

Subsequently, the tracking residual ΔZ between the measured tracking amount of the exposure apparatus 10 and the actual focal position with respect to the surface position (surface shape) of the wafer 25 measured in Step S11 is obtained (Step S13). That is, the difference corresponding to the non-tracking amount of the focal position is obtained.

Subsequently, the difference corresponding to the wavelength of the exposure light L and the non-tracking amount of the focal position, that is, the optical path difference according to the tracking residual ΔZ is calculated (Step S14). The “optical path difference” refers to a value obtained by converting the tracking residual ΔZ by the refractive index of the medium at the exposure wavelength.

Next, a photomask 21 as a step mask for pattern transfer is created so that the focal position when the optical path difference calculated in Step S14 is provided is within the range of the depth of focus with respect to the surface position of the wafer 25.

Then, a pattern is transferred to the wafer 25 having the unevenness of the surface of the resist 26 using the created photomask 21 (Step S15).

As a result, according to the configuration of the present embodiment, the focal position FC can always be set within the depth of focus with respect to the surface position (surface shape) of the wafer 25, so that it is possible to suppress transfer failure and prevent yield loss.

### [1] First Embodiment

Next, the detailed configuration of the photomask 21 as a step mask of the first embodiment will be described.

FIG. 4 is an explanatory diagram of an example of a surface shape (cross-sectional shape) of a resist.

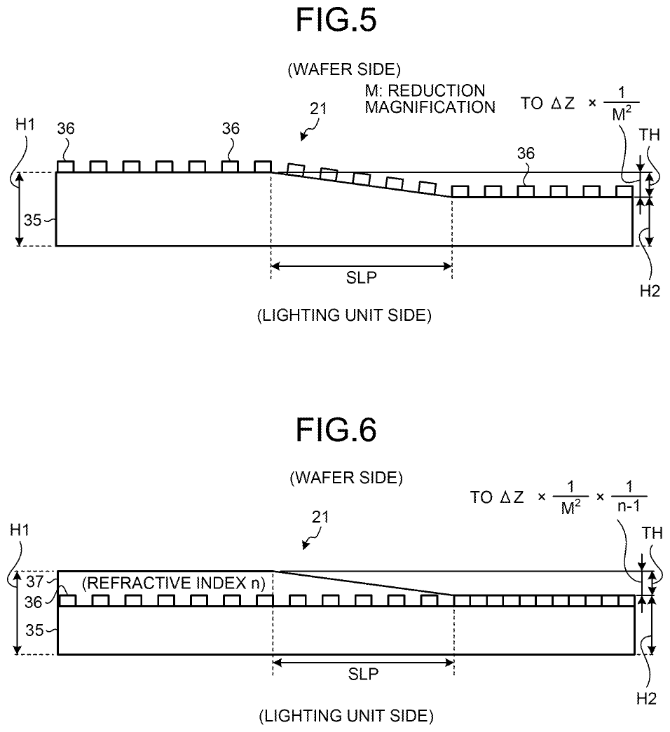

FIG. 5 is an explanatory diagram of a configuration example of a photomask of a first embodiment corresponding to the resist of FIG. 4.

As illustrated in FIG. 4, the tracking residual ΔZ is generated with respect to the resist 26.

In this case, the reduction magnification of the projection unit 15 as a reduction projection optical system of the exposure apparatus 10 is M.

As illustrated in FIG. 5, the photomask substrate 35 has a portion having a first height H1, a portion having a second height H2 (<H1), and a slope portion SLP formed between the portions.

In this case, in the first embodiment, as illustrated in FIG. 5, the difference in thickness (difference between heights H1 and H2) TH (corresponding to the optical path length) of the photomask substrate 35 constituting the photomask 21 is set to the thickness (optical path length) shown in the following equation based on the tracking residual ΔZ and the reduction magnification M generated corresponding to the exposure position of the resist 26.

TH≈ΔZ·1/M²

On the photomask substrate 35, a plurality of light-shielding bodies 36 for reducing the amount of exposure light L are provided, for example, at equal intervals.

The photomask substrate 35 contains a material such as synthetic quartz. The light-shielding body 36 contains, for example, a metallic material such as chromium (Cr).

By performing exposure using the photomask 21 having such a configuration, it is possible to compensate for the tracking residual ΔZ that cannot be compensated by the projection unit 15. Therefore, the focal position FC of the actual exposure light L can be contained within the range of the depth of focus defined by the projection unit 15, and the pattern can be transferred onto the surface of the resist 26 with desired accuracy.

### [2] Second Embodiment

In the first embodiment, the optical path length for compensating the tracking residual ΔZ, that is, the thickness of the photomask substrate 35 is changed according to the irradiation position of the exposure light L, and further to the irradiation position of the exposure light L of the resist 26. However, in a second embodiment, the photomask substrate 35 has uniform thickness and has a flat surface, and an optical path difference adjusting member 37 is formed on the upper surface of the photomask substrate 35 and the light-shielding body 36 on the wafer side.

FIG. 6 is an explanatory diagram of a configuration example of a photomask of a second embodiment corresponding to the resist of FIG. 4.

Also in this case, as in the first embodiment, the reduction magnification of the projection unit 15 as a reduction projection optical system of the exposure apparatus 10 is M.

In the second embodiment, the thickness of the photomask substrate 35 constituting the photomask 21 is constant (flat).

On the photomask substrate 35, a plurality of light-shielding bodies 36 for reducing the amount of exposure light L are provided, for example, at equal intervals.

The optical path difference adjusting member 37 is stacked on the upper surface of the surface of the photomask substrate 35 on the wafer 25 side.

As illustrated in FIG. 6, the photomask 21 has a portion having a first height H1 in which the optical path difference adjusting member 37 is stacked on the photomask substrate 35, a portion having a second height H2 (<H1), and a slope portion SLP formed between the portions. Further, the thickness of the thinnest portion of the optical path difference adjusting member 37 is set to be the same as the thickness of the light-shielding body 36.

In this case, the difference in thickness (difference between heights H1 and H2) TH (corresponding to the optical path length) of the photomask 21 including the optical path difference adjusting member 37 is set to the thickness (optical path length) shown in the following equation based on the tracking residual ΔZ, the reduction magnification H generated corresponding to the exposure position of the resist 26, and a refractive index n of the optical path difference adjusting member 37.

TH≈ΔZ·1/M²·1/(n−1)

In this case, it is more preferable that the refractive index n of the optical path difference adjusting member 37 has a small difference from the refractive index of the photomask substrate 35. That is, most preferably, the refractive indexes are the same (including the case of the same material), but they may be different. The optical path difference adjusting member 37 includes a material such as synthetic quartz.

By performing exposure using such a photomask 21 of the second embodiment, as similar to the first embodiment, it is possible to compensate for the tracking residual ΔZ that cannot be compensated by the protection unit 15. Therefore, the focal position FC of the actual exposure light L can be contained within the range of the depth of focus defined by the projection unit 15, and the pattern can be transferred onto the surface of the resist 26 with desired accuracy.

### [3] Third Embodiment

In the second embodiment, the thickness of the thinnest portion of the optical path difference adjusting member 37 is set to be the same as the thickness of the light-shielding body 36. However, in a third embodiment, the thickness of the thinnest portion of the optical path difference adjusting member 37 is formed to be thicker than the thickness of the light-shielding body 36.

That is, in the third embodiment, the optical path difference adjusting member 37 is stacked on the wafer 25 side of all the light-shielding bodies 36.

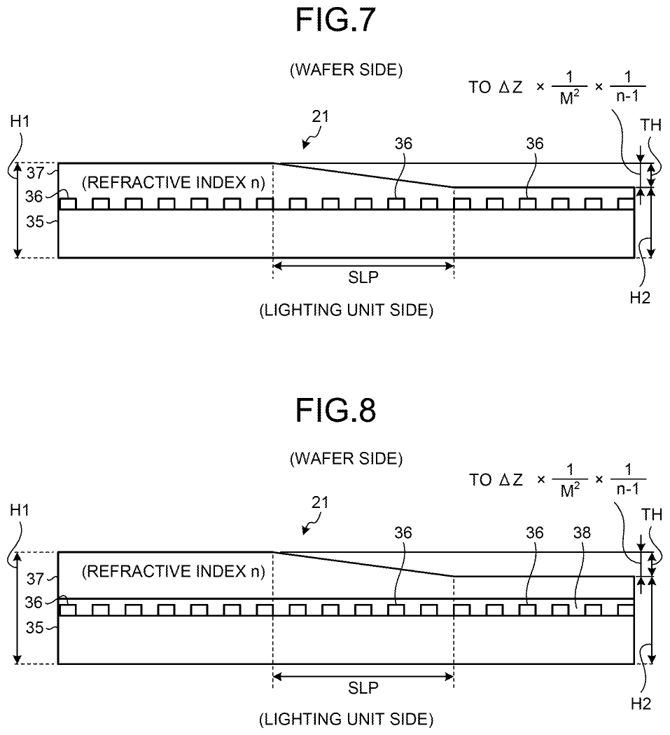

FIG. 7 is an explanatory diagram of a configuration example of a photomask of a third embodiment corresponding to the resist of FIG. 4.

Also in this case, as in the first embodiment, the reduction magnification of the projection unit 15 as a reduction projection optical system of the exposure apparatus 10 is M.

In the third embodiment, as in the second embodiment, the thickness of the photomask substrate 35 constituting the photomask 21 is constant and has a flat surface.

On the photomask substrate 35, a plurality of light-shielding bodies 36 for reducing the amount of exposure light L are provided, for example, at equal intervals.

The optical path difference adjusting member 37 is stacked on the upper surface of the surface of the photomask substrate 35 on the wafer 25 side so as to cover all the light-shielding bodies.

As illustrated in FIG. 7, the photomask 21 has a portion having a first height H1 in which the optical path difference adjusting member 37 is stacked on the photomask substrate 35, a portion having a second height H2 (<H1), and a slope portion SLP formed between the portions.

In this case, the difference in thickness between the thickest portion (left side portion in FIG. 7) and the thinnest portion (right side portion in FIG. 7) TH1 (corresponding to the optical path length) of the photomask 21 including the optical path difference adjusting member 37 is set to the thickness (optical path length) shown in the following equation based on the tracking residual ΔZ, the reduction magnification M generated corresponding to the exposure position of the resist 26, and a refractive index n of the optical path difference adjusting member 37.

TH1≈ΔZ·1/M²·1/(n−1)

In this case as well, as in the second embodiment, it is more preferable that the refractive index n of the optical path difference adjusting member 37 has a small difference from the refractive index of the photomask substrate 35. That is, most preferably, the refractive indexes are the same (including the case of the same material).

By performing exposure using such a photomask 21 of the third embodiment, as similar to the first and second embodiments, it is possible to compensate for the tracking residual LIZ that cannot be compensated by the projection unit 15. Therefore, the focal position FC of the actual exposure light L can be contained within the range of the depth of focus defined by the projection unit 15, and the pattern can be transferred onto the surface of the resist 26 with desired accuracy.

### [4] Fourth Embodiment

In the above second and third embodiments, the optical path difference adjusting member 37 is provided directly on the photomask 21. However, in a fourth embodiment, a pellicle provided as a prevention and protective film on the photomask 21 itself is an optical path difference adjusting member.

FIG. 8 is an explanatory diagram of a configuration example of a photomask of a fourth embodiment corresponding to the resist of FIG. 4.

Also in this case, as in the first embodiment, the reduction magnification of the projection unit 15 as a reduction projection optical system of the exposure apparatus 10 is M.

In the fourth embodiment as well, as in the second embodiment, the thickness of the photomask substrate 35 constituting the photomask 21 is constant and has a flat surface.

On the photomask substrate 35, a plurality of light-shielding bodies 36 for reducing the amount of exposure light L are provided, for example, at equal intervals.

A pellicle 38 provided as a dustproof protective film for protecting the photomask 21 from dirt, dust and the like, and the optical path difference adjusting member 37 are stacked on the upper surface of the surface of the photomask substrate 35 on the wafer 25 side. The pellicle 38 may also function as a part of the optical path difference adjusting member 37.

In this case as well, as similar to the third embodiment, as illustrated in FIG. 8, the photomask 21 has a portion having a first height H1 in which the pellicle 38 and the optical path difference adjusting member 37 is stacked on the photomask substrate 35, a portion having a second height H2 (<H1), and a slope portion SLP formed between the portions.

Then, the difference in thickness between the thickest portion (left side portion in FIG. 8) and the thinnest portion (right side portion in FIG. 8) TH1 (corresponding to the optical path length) of the photomask 21 including the optical path difference adjusting member 37 and the pellicle 38 is set to the thickness (optical path length) shown in the following equation based on the tracking residual ΔZ, the reduction magnification M generated corresponding to the exposure position of the resist 26, and a refractive index n of the optical path difference adjusting member 37.

TH1≈ΔZ·1/M²·1/(n−1)

In this case as well, as in the second and third embodiments, it is more preferable that the refractive index n of the optical path difference adjusting member 37 has a small difference from the refractive index of the photomask substrate 35. That is, most preferably, the refractive indexes are the same (including the case of the same material).

By performing exposure using such a photomask 21 of the fourth embodiment, as similar to the first and second embodiments, it is possible to compensate for the tracking residual ΔZ that cannot be compensated by the projection unit 15. Therefore, the focal position FC of the actual exposure light L can be contained within the range of the depth of focus defined by the projection unit 15, and the pattern can be transferred onto the surface of the resist 26 with desired accuracy.

### [5] Fifth Embodiment

In each of the above embodiments, the light-shielding bodies 36 are provided at equal intervals. However, in the fifth embodiment, the light-shielding bodies 36 are provided at intervals according to the amount of optical path difference adjustment, so that the optical image intensity is made substantially constant regardless of the exposure position of the resist 26 to perform more uniform exposure.

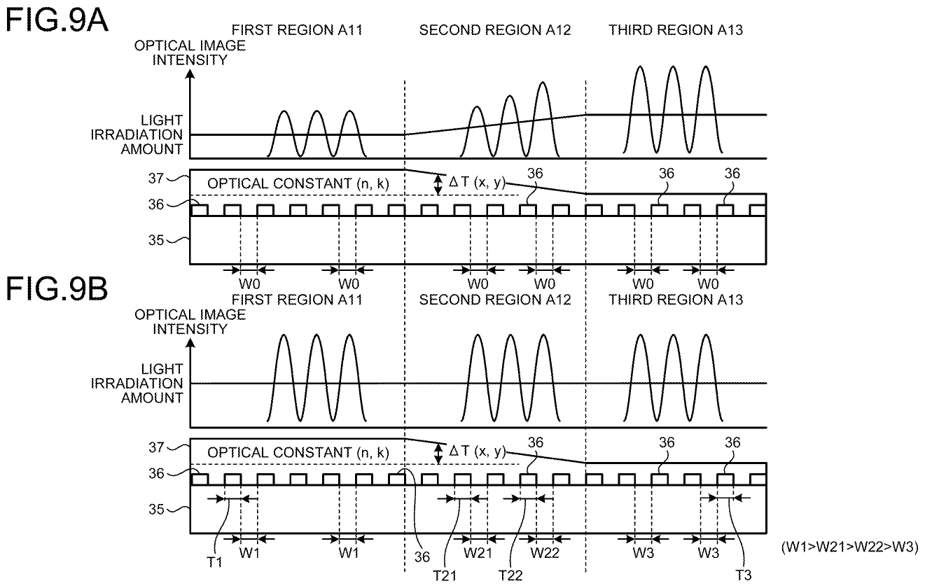

FIGS. 9A to 9B are explanatory diagrams of the fifth embodiment.

FIG. 9A is an explanatory diagram of the optical image intensity at the focal position FC when the light-shielding bodies 36 are provided at equal intervals. FIG. 9B is an explanatory diagram of the optical image intensity at the focal position FC when the interval between the adjacent light-shielding bodies 36 is changed.

When optical constants (n, k) are set, as illustrated in FIG. 9A, the optical path difference adjusting member 37 is thicker, an effective light irradiation amount is decreases more due to the increase in the amount of attenuation proportional to the thickness of the optical path difference adjusting member 37 of the exposure light L, and the optical image intensity decreases more.

More specifically, in the first region A11 where the thickness of the optical path difference adjusting member 37 is the thickest, the irradiation amount of the exposure light L is most decreased and the optical image intensity (see the wavy waveform) is small.

Then, in the second region A12 where the thickness of the optical path difference adjusting member 37 gradually decreases, the irradiation amount of the exposure light L gradually increases, and the optical image intensity gradually increases.

In the third region A13 where the thickness of the optical path difference adjusting member 37 is the thinnest, the irradiation amount of the exposure light L is most increased and the optical image intensity (see the wavy waveform) is the largest.

Therefore, it can be seen that the drawing accuracy of the pattern transferred to the surface of the resist 26 gradually increases in the order of the first region A11, the second region A12, and the third region A13.

Therefore, in the fifth embodiment, in all of the first region A11 to the third region A13, in order to improve the drawing accuracy, as illustrated in FIG. 9B, as the optical path difference adjusting member 37 is thicker, the width of the light-shielding body 36 is reduced and the arrangement interval between the light-shielding bodies 36 is increased so that the amount of transmitted light is increased. Further, as the thickness of the optical path difference adjusting member 37 is thinner, the width of the light-shielding body 36 is increased and the arrangement interval of the light-shielding body 36 is reduced, so that the amount of transmitted light is reduced. At this time, the sum of a width Tj of the adjacent light-shielding bodies and an arrangement interval Wj is made to constant.

More specifically, when the width of the light-shielding body 36 in the first region A11 where the thickness of the optical path difference adjusting member 37 is the thickest is T1, the arrangement interval is W1, the width and arrangement interval of the light-shielding body 36 in the second region where the thickness of the optical path difference adjusting member 37 gradually decreases are changed proportional to the thickness of the optical path difference adjusting member 37 in the order of T1, . . . , T21, . . . , T22, . . . , and (T3), and W1, . . . , W21, . . . , W22, . . . , (W3), respectively, and the arrangement interval of the light-shielding body 36 in the third region A13 where the thickness of the optical path difference adjusting member 37 is the thinnest is W3, the arrangement interval is set so as to have the relationship below.

W1>W21>W22>W3

Wherein, T1+W1=T21+W21=T22+W22=T3+W3=constant

As a result, the irradiation amount of the exposure light L becomes constant in all of the first region A11 to the third region A13, and the optical image intensity (see the wavy waveform) also becomes constant.

That is, the pattern drawing accuracy can be kept constant.

In this case, the irradiation amount of the exposure light L is set so that the pattern drawing accuracy is higher, and the arrangement interval of the light-shielding body 36 is set accordingly.

As a result of the above, by additionally applying the fifth embodiment to each of the above embodiments, in addition to the effect of each embodiment, the drawing accuracy of the pattern can be kept uniform regardless of the exposure position of the resist 26, and exposure processing with high accuracy can be performed.

In the first to fifth embodiments described above, the photomask substrate 35 or the optical path difference adjusting member 37 has a slope portion. By having the slope portion, even when there is a steep step on the resist 26 (see FIG. 2) on the exposed substrate side, it is possible to reduce the influence of the exposure due to the step. Further, with the slope portion, it is possible to form a pattern of the light-shielding body also on the slope portion.

### [6] Photomask Substrate Creation Method

Next, a photomask substrate creation method will be described.

First, a photomask substrate creation method of the first embodiment will be described.

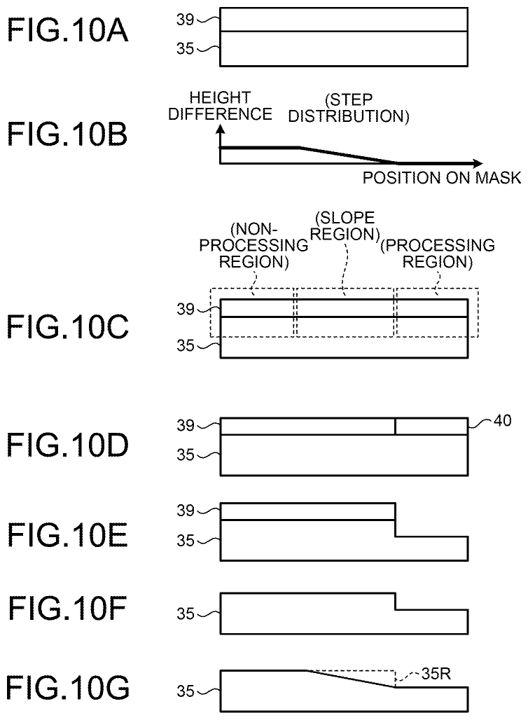

FIGS. 10A to 10G are flowcharts of first creation processing of a photomask substrate of the first embodiment.

First, a creator applies resist 39 on the photomask substrate 35 (see FIG. 10A).

Next, the step distribution information corresponding to the wafer 25 to be exposed is acquired (see FIG. 10B).

Subsequently, based on the acquired step distribution information, a non-processing region that does not need to be processed on the photomask substrate 35, a slope region that needs a slope formed on the photomask substrate 35, and a processing region that needs reduction of the thickness of the photomask substrate 35 to a predetermined thickness are identified (see FIG. 10C).

Then, the resist 39 is exposed to the processing region by a laser drawing device to form the resist exposure region 40 (see FIG. 10D).

Subsequently, the exposed resist 39 is developed and the processing region is etched (wet etching or dry etching) (see FIG. 10E).

Next, the remaining resist 39 is removed (see FIG. 10F).

Subsequently, etching (wet etching or dry etching) and chemical mechanical polishing (CMP) are performed on the slope region, which is the region between the etched processing region and the non-processing region, to remove the resist 35R and form a slope (see FIG. 10G).

As a result, the photomask substrate 35 illustrated in FIG. 5 can be obtained.

Next, a second creation method of the photomask substrate of the first embodiment will be described.

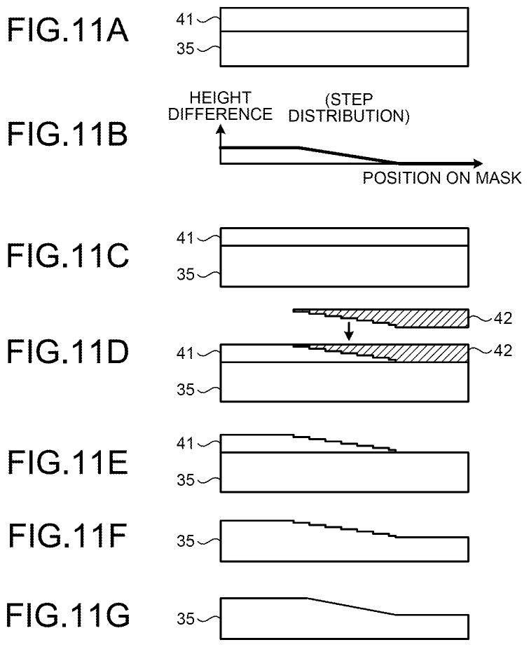

FIGS. 11A to 11G are flowcharts of second creation processing of the photomask substrate of the first embodiment.

First, the creator applies a thermosetting or ultraviolet curable resin 41 on the photomask substrate 35 (see FIG. 11A).

Next, the step distribution information corresponding to the wafer 25 to be exposed is acquired (see FIG. 11B).

Subsequently, a template 42 having a shape based on the acquired step distribution information is prepared (see FIG. 11C).

Then, the resin 41 is cured while the template 42 is pressed against the resin 41 before curing (see FIG. 11D).

Then, the template 42 is removed (see FIG. 11E).

Further etching (wet etching or dry etching) is performed using the resin 41 remaining after curing as a processing mask (see FIG. 11F).

Subsequently, chemical mechanical polishing (CMP) is performed to form a slope (see FIG. 11G).

As a result, the photomask substrate 35 illustrated in FIG. 5 can also be obtained by this creation method.

Subsequently, a method of forming a light-shielding body 36 on the photomask substrate 35 of the first embodiment to create a photomask will be described.

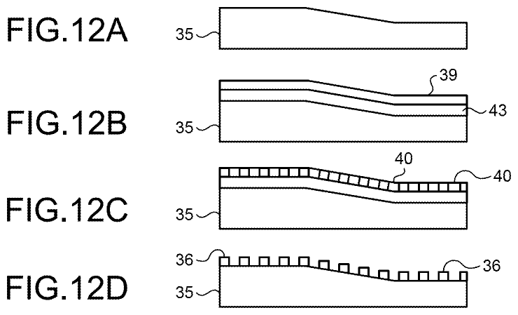

FIGS. 12A to 12D are flowcharts of light-shielding body forming processing.

The photomask substrate 35 obtained by the above-mentioned first or second creation processing is prepared (see FIG. 12A).

Subsequently, the light-shielding film layer 43 and the resist 39 for forming the light-shielding body 36 are stacked on the photomask substrate 35 (see FIG. 12B).

Then, the resist 39 is exposed to the processing region by a laser drawing device to form the resist exposure region 40 (see FIG. 12C).

Subsequently, the exposed resist 39 is developed and etching (wet etching or dry etching) is performed (see FIG. 12D).

As a result, it is possible to obtain the photomask 21 in which the light-shielding body 36 is formed on the photomask substrate 35 illustrated in FIG. 5.

Next, a photomask substrate creation method of the second embodiment will be described.

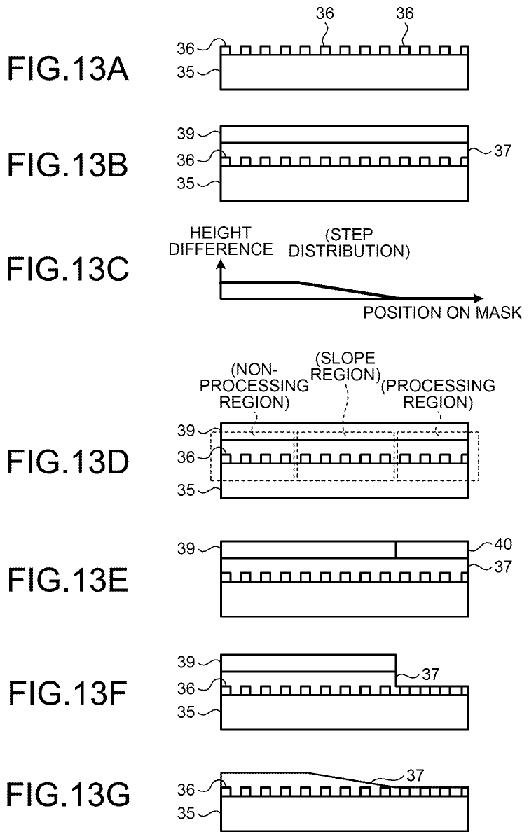

FIGS. 13A to 13G are flowcharts of creation processing of a photomask substrate of the second embodiment.

First, the creator stacks the light-shielding film layer and the resist 39 for forming the light-shielding body 36 on the photomask substrate 35 having a uniform thickness. Then, the creator performs exposure of the resist 39 by a laser drawing device to form the resist exposure region 40. Subsequently, the exposed resist 39 is developed and etched (wet etching or dry etching) to obtain the photomask substrate 35 having the light-shielding body 36 formed on the upper surface illustrated in FIG. 6 (see FIG. 13A).

Subsequently, the resist 39 is applied onto the photomask substrate 35 on the side where the light-shielding body 36 is formed (see FIG. 13B).

Next, the step distribution information corresponding to the wafer 25 to be exposed is acquired (see FIG. 13C).

Subsequently, based on the acquired step distribution information, a non-processing region that does not need to be processed on the photomask substrate 35, a slope region that needs a slope formed on the photomask substrate 35, and a processing region that needs reduction of the thickness of the photomask substrate 35 to a predetermined thickness are identified (see FIG. 13D).

Then, the resist 39 is exposed to the processing region by a laser drawing device to form the resist exposure region 40 (see FIG. 13E).

Subsequently, the exposed resist 39 is developed and the processing region is etched (wet etching or dry etching) (see FIG. 13F).

Next, etching (wet etching or dry etching) and chemical mechanical polishing (CMP) are performed on the slope region, which is the region between the etched processing region and the non-processing region, to form a slope (see FIG. 13G).

As a result, the photomask 21 illustrated in FIG. 6 can be obtained.

### [7] Sixth Embodiment

Next, a photomask substrate creation method of the sixth embodiment will be described.

The difference from the sixth embodiment is that the optical path difference adjusting member is created in a different process from that of the photomask substrate 35 on which the light-shielding body 36 is formed, and the created optical path difference adjusting member is bonded to the photomask substrate 35 on which the light-shielding body 36 is formed to create the photomask 21.

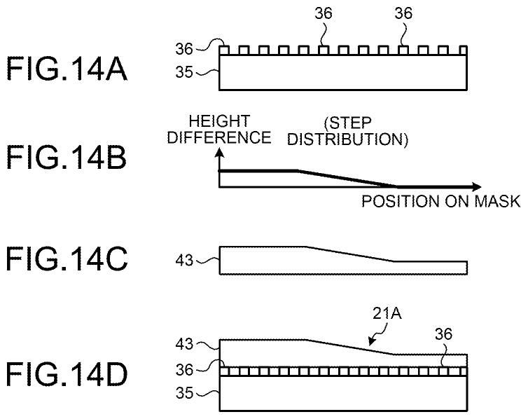

FIGS. 14A to 14D are flowcharts of creation processing of a photomask substrate of a sixth embodiment.

First, the creator creates or obtains the photomask substrate 35 having the light-shielding body 36 formed on the upper surface in the same manner as the creation method of the photomask substrate of the second embodiment (see FIG. 14A).

At the same time, the step distribution information corresponding to the wafer 25 to be exposed is acquired (see FIG. 14B).

Subsequently, based on the step distribution information acquired, the optical path difference adjusting member 43 corresponding to the step distribution is created by a 3D printer or the like (see FIG. 14C).

Then, the created optical path difference adjusting member 43 is bonded to the surface side of the photomask substrate 35 on which the light-shielding body 36 is formed with an adhesive or the like, so that a photomask 21A having a similar function to that of the photomask 21 of the second embodiment can be obtained.

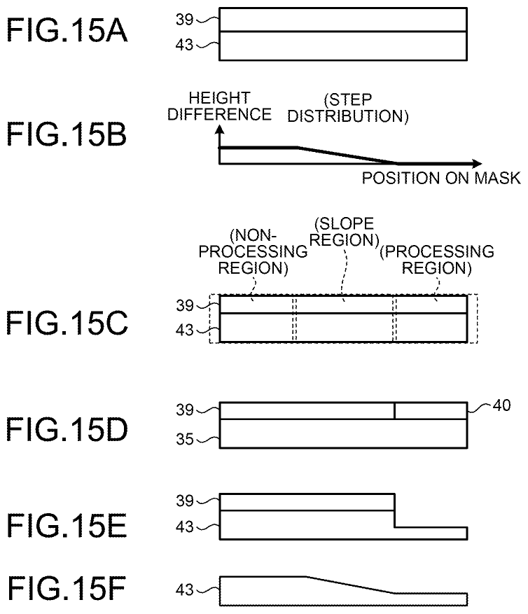

FIGS. 15A to 15F are explanatory diagrams of another creation method of an optical path difference adjusting member used in the sixth embodiment.

In the sixth embodiment, the optical path difference adjusting member 43 is created by a 3D printer or the like. However, a method of creating the optical path difference adjusting member 43 in a similar manner to the photomask substrate will be described below.

First, the creator applies the resist 39 on the optical path difference adjusting member 43 having a uniform thickness (see FIG. 15A).

Next, the step distribution information corresponding to the wafer 25 to be exposed is acquired (see FIG. 15B).

Subsequently, based on the acquired step distribution information, a non-processing region that does not need to be processed on the optical path difference adjusting member 43, a slope region that needs a slope formed on the optical path difference adjusting member 43, and a processing region that needs reduction of the thickness of the optical path difference adjusting member 43 to a predetermined thickness are identified (see FIG. 15C).

Then, the resist 39 is exposed to the processing region by a laser drawing device to form the resist exposure region 40 (see FIG. 15D).

Subsequently, the exposed resist 39 is developed and the processing region is etched (wet etching or dry etching) (see FIG. 15E).

Next, the remaining resist 39 is removed, etching (wet etching or dry etching) and chemical mechanical polishing (CMP) are performed on the slope region, which is the region between the etched processing region and the non-processing region, to form a slope (see FIG. 15F).

As a result, the optical path difference adjusting member 43 illustrated in FIG. 14 can be obtained, and furthermore, the photomask 21A of the sixth embodiment can be obtained.

### [8] Effects of First to Sixth Embodiments

As described above, according to the photomasks 21 and 21A of the first to sixth embodiments, in the exposure apparatus, it is possible to reduce the influence of the reduction of the followability (occurrence of tracking residual) of the focus shift function due to the influence of the step between the cell region and the peripheral circuit region of the semiconductor wafer, reduce the yield loss due to transfer failure, and improve the yield.

### [9] Appendix

There are other embodiments of the present invention as below.

### [9.1] First Other Embodiment

A photomask substrate creation method including:

acquiring step distribution information on a step formed on a photomask;

irradiating a quartz substrate having a resist formed on one surface with an energy ray based on the step distribution information;

developing the resist, processing the quartz substrate using the resist as a processing mask, and removing the resist after processing; and

forming a slope connecting a processing region and a non-processing region in a region between the processing region and the non-processing region of the quartz substrate after processing.

### [9.2] Second Other Embodiment

A photomask substrate creation method including;

acquiring step distribution information on a step formed on a photomask;

creating a template having a predetermined step distribution based on the step distribution information;

curing a resin layer while pressing the template on a quartz substrate having the resin layer formed on one surface;

processing the quartz substrate using the resin layer from which the template has been removed as a processing mask; and

forming a slope connecting a processing region and a non-processing region in a region between the processing region and the non-processing region of the quartz substrate after processing.

### [9.3] Third Other Embodiment

A photomask creation method,

the photomask having a photomask substrate and a plurality of light-shielding bodies formed on the photomask substrate on the substrate side, the photomask creation method including:

acquiring step distribution information formed on the photomask;

stacking an optical path difference adjusting layer and a resist layer on a surface side of the photomask substrate on which the light-shielding bodies are formed;

irradiating the resist layer with an energy ray based on the step distribution information;

developing the resist layer, processing the optical path difference adjusting layer using the resist layer as a processing mask, and removing the resist layer after processing; and

forming a slope connecting a processing region and a non-processing region in a region between the processing region and the non-processing region of the optical path difference adjusting layer after processing.

In this case, forming the slope may include processing using a CMP.

### [9.4] Fourth Other Embodiment

A photomask creation method,

the photomask having a photomask substrate and a plurality of light-shielding bodies formed on the photomask substrate on the substrate side, the photomask creation method including:

acquiring step distribution information formed on the photomask;

forming an optical path difference adjusting member having predetermined step distribution based on the step distribution information; and

bonding the optical path difference adjusting member to a surface side of the photomask on which the light-shielding bodies are formed.

In this case, forming the optical path difference adjusting member may include stacking the optical path difference adjusting member by a 3D printer based on the step distribution information to form the optical path difference adjusting member.

Forming the optical path difference adjusting member may include:

stacking a resist layer on the optical path difference adjusting member;

irradiating the resist layer with an energy ray based on the step distribution information;

developing the resist layer, processing the optical path difference adjusting member using the resist layer as a processing mask, and removing the resist layer after processing; and

forming a slope connecting a processing region and a non-processing region in a region between the processing region and the non-processing region of the optical path difference adjusting member after processing.

Forming the slope may include processing using a CMP.

What is claimed is:

1. A pattern forming method comprising:
preparing a photomask including at least a photomask substrate and a plurality of light-shielding bodies formed on the photomask substrate, the photomask including a first region having a first height, a second region having a second height different from the first height, and a slope provided between the first region and the second region and connecting the first height and the second height; and
transferring a pattern to a substrate using the photomask.

2. The pattern forming method according to claim 1,
wherein the photomask has a shape corresponding to an optical path difference according to a difference between a height difference of the substrate and a focus shift following amount with respect to the height difference of the substrate.

3. The pattern forming method according to claim 1,
wherein the photomask includes an optical path difference adjusting member.

4. The pattern forming method according to claim 3,
wherein the optical path difference adjusting member includes a pellicle.

5. The pattern forming method according to claim 2,
wherein a width of each of the light-shielding bodies is changed according to the optical path difference.

6. A photomask creation method comprising:
sequentially stacking a light-shielding body layer and a resist layer on a quartz substrate on which a slope is formed;
irradiating the resist layer with an energy ray; and
developing the resist layer, processing a substrate of the light-shielding body layer using the resist layer as a processing mask, and removing the resist layer after processing.

7. The photomask creation method according to claim 6,
wherein forming the slope including processing using a CNP.

8. A photomask comprising at least:
a photomask substrate; and
a plurality of light-shielding bodies formed on the photomask substrate,
the photomask including a first region having a first height, a second region having a second height different from the first height, and a slope provided between the first region and the second region and connecting the first height and the second height.

9. The photomask according to claim 8,
further comprising an optical path difference adjusting member provided on the photomask substrate and the light-shielding bodies.

10. The photomask according to claim 8
wherein the slope is provided with the plurality of light-shielding bodies.

11. The photomask according to claim 8,
wherein the photomask substrate includes the slope.

12. The photomask according to claim 8,
wherein the photomask substrate has a flat surface, and the optical path difference adjusting member includes the slope.

13. The photomask according to claim 12,
further comprising a pellicle provided between the photomask substrate and the optical path difference adjusting member.

14. The photomask according to claim 8,
wherein a thickness of a thinnest portion of the optical path difference adjusting member is substantially equal to a thickness of each of the light-shielding bodies.

15. The photomask according to claim 8,
wherein a thickness of a thinnest portion of the optical path difference adjusting member is thicker than a thickness of each of the light-shielding bodies.
